(19) United States
(12) Patent Application Publication
(10) Pub. No.: US 2018/0212623 A1
(43) Pub. Date: Jul. 26, 2018

(54) CONTROLLER AND OPERATING METHOD THEREOF

(71) Applicant: SK hynix Inc., Gyeonggi-do (KR)

(72) Inventor: Se-Hyun KIM, Seoul (KR)

(21) Appl. No.: 15/687,631

(22) Filed: Aug. 28, 2017

(30) Foreign Application Priority Data
Jan. 26, 2017 (KR) 10-2017-0012933

(51) Int. Cl. H03M 13/11; H03M 13/00

(52) U.S. Cl. CPC H03M 13/1111; H03M 13/611

(57) ABSTRACT

A controller includes a processor suitable for determining whether to store further data corresponding to a command from a host into a first region in a main memory of the host when receiving the command from the host, requesting the host to store the further data corresponding to the command into the first region of the main memory when the first region is determined to store the further data corresponding to the command; and an error correction code unit suitable for encoding the further data stored in the first region in response to the storage request. The processor may control a memory device to store the encoded data.

### CROSS-REFERENCE TO RELATED APPLICATIONS

The present application claims priority of Korean Patent Application No. 10-2017-012933, filed on Jan. 26, 2017, which is incorporated herein by reference in its entirety.

### BACKGROUND

### 1. Field

Various exemplary embodiments of the present invention relate to a controller and, more particularly, to a controller capable of processing data to and from a memory device, and an operating method thereof.

### 2. Description of the Related Art

The computer environment paradigm has changed to ubiquitous computing systems that can be used anytime and anywhere. Due to this, use of portable electronic devices such as mobile phones, digital cameras, and notebook computers has rapidly increased. These portable electronic devices generally use a memory system having one or more memory devices for storing data. A memory system may be used as a main memory or an auxiliary memory of a portable electronic device.

Memory systems provide excellent stability, durability, high information access speed, and low power consumption because they have no moving parts. Examples of memory systems having such advantages include universal serial bus (USB) memory devices, memory cards having various interfaces, and solid state drives (SSD).

### SUMMARY

Various embodiments of the present invention are directed to a controller, and a memory system employing the same, capable of improved data processing. The controller and the memory system may more promptly process data to a memory device.

In accordance with an embodiment of the present invention, a controller for a memory system may include a processor suitable for determining whether to store further data corresponding to a command received from a host into a first region in a main memory of the host when receiving the command from the host, requesting the host to store the further data corresponding to the command into the first region of the main memory when the first region is determined to store the further data corresponding to the command; and an error correction code unit suitable for encoding the further data stored in the first region in response to the storage request. The processor may control a memory device which is coupled to the controller to store the encoded data.

The first region may be a part of the main memory of the host, into which the host stores the further data corresponding to the command in response to the storage request.

The processor may determine to store the further data into the first region in the main memory of the host when there is an invalid data among data stored in the first region.

When the further data corresponding to the command is stored into the first region of the main memory and then stored in the memory device, the further data stored in the first region of the main memory may become invalid.

The processor may further request the host to increase a storage capacity of the first region of the main memory when the processor determines not to store the further data into the first region in the main memory.

When the host increases the storage capacity of the first region of the main memory, the processor may request the host to store data corresponding to the command through the increased storage capacity of the first region.

The processor may further generate metadata for the encoded data stored in the memory device. The processor may further request the host to store the metadata into a second region of the main memory.

The second region may be a part of the main memory, into which the host stores the metadata in response to the storage request.

When a size of the data corresponding to the command stored in the first region is smaller than a predetermined size, the error correction code unit may add dummy data to the data corresponding to the command stored in the first region before encoding the data stored in the first region.

The controller may further include a memory. The processor may further store the data corresponding to the command into the memory when processor determines not to store data into the first region in the main memory. The error correction code unit may further encode the data corresponding to the command stored in the memory.

In accordance with an embodiment of the present invention, an operating method of a controller including a processor and an error correction code unit may include: determining, by the processor, whether to store further data corresponding to a command received from a host into a first region of a main memory of the host when the processor receives the command from the host; requesting, by the processor, the host to store the further data corresponding to the received command into the first region of the main memory when the first region of the main memory is determined to store the further data corresponding to the received command; encoding, by the error correction code, data stored in the first region in response to the storage request; and controlling, by the processor, a memory device to store the encoded data.

The first region may be a part of the main memory, into which the host stores the further data corresponding to the command in response to the storage request.

The determining may be performed by determining to store the further data corresponding to the received command into the first region in the main memory of the host when there is an invalid data among data stored in the first region.

When the further data corresponding to the command is stored into the first region of the main memory and then stored in the memory device, the further data stored in the first region of the main memory may become invalid.

The method may further include requesting, by the processor, the host to increase a storage capacity of the first region of the main memory when the processor determines not to store the further data corresponding to the received command into the first region in the main memory.

When the storage capacity of the first region of the main memory is increased by the host, the requesting by the processor may perform to store data corresponding to the command through the increased storage capacity of the first region.

The method may further Include generating, by the processor, metadata for the encoded data stored in the memory device, and requesting, by the processor, the host to store the metadata into a second region of the main memory.

The second region may be a part of the main memory, into which the host stores the metadata in response to the storage request.

When the size of the further data of the command which are to be stored in the first region is smaller than a predetermined size, the encoding by the error correction code unit may include adding dummy data to the data corresponding to the command stored in the first region before encoding the further data stored in the first region.

The method may further include storing, by the processor, the data corresponding to the command into the memory when processor determines not to store the further data into the first region of the main memory, and encoding, by the error correction code unit, the further data corresponding to the command stored in the main memory.

In accordance with an embodiment of the present invention, a controller may promptly and stably process data to a memory device with minimized complexity and performance degradation of a memory system and with maximized use efficiency of a memory device.

### BRIEF DESCRIPTION OF THE DRAWINGS

FIG. 1 is a block diagram illustrating a data processing system including a memory system, in accordance with an embodiment of the present invention.

FIG. 2 is a schematic diagram illustrating an exemplary configuration of a memory device employed in the memory system shown in FIG. 1.

FIG. 3 is a circuit diagram Illustrating an exemplary configuration of a memory cell array of a memory block in the memory device shown in FIG. 2.

FIG. 4 is a schematic diagram illustrating an exemplary three-dimensional structure of the memory device shown in FIG. 2.

FIG. 5 is a diagram schematically illustrating the data processing system shown in FIG. 1.

FIG. 6 is a flowchart illustrating an operation of the memory system, in accordance with an embodiment of the present invention.

FIGS. 7 to 15 are diagrams schematically illustrating application examples of the data processing system, in accordance with various embodiments of the present invention.

### DETAILED DESCRIPTION

Various embodiments of the present invention are described below in more detail with reference to the accompanying drawings. We note, however, that the present invention may be embodied in different other embodiments, forms and variations thereof and should not be construed as being limited to the embodiments set forth herein.

Rather, the described embodiments are provided so that this disclosure will be thorough and complete, and will fully convey the present invention to those skilled in the art to which this invention pertains. Throughout the disclosure, like reference numerals refer to like parts throughout the various figures and embodiments of the present invention.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order to clearly illustrate various features of the embodiments.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The terminology used herein is for the purpose of describing particular embodiments only and is not intended to be limiting of the present invention. As used herein, singular forms are intended to include the plural forms as well, unless the context clearly indicates otherwise. It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs in view of the present disclosure. It will be further understood that terms, such as those defined in commonly used dictionaries, should be interpreted as having a meaning that is consistent with their meaning in the context of the present disclosure and the relevant art and will not be interpreted in an idealized or overly formal sense unless expressly so defined herein.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

It is also noted, that in some instances, as would be apparent to those skilled in the relevant art, a feature or element described in connection with one embodiment may be used singly or in combination with other features or elements of another embodiment, unless otherwise specifically indicated.

Hereinafter, the various embodiments of the present invention will be described in detail with reference to the attached drawings.

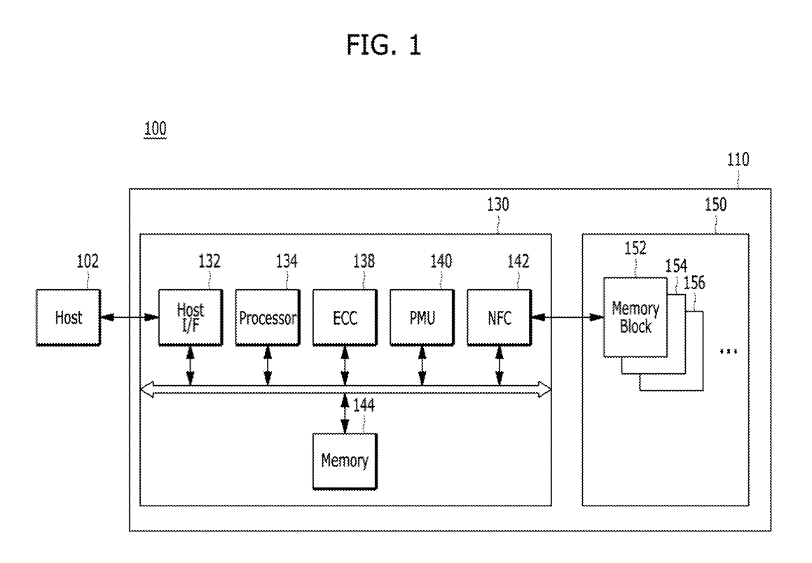

FIG. 1 is a block diagram illustrating a data processing system 100 including a memory system 110 in accordance with an embodiment of the present invention.

Referring to FIG. 1, the data processing system 100 may include a host 102 and the memory system 110.

The host 102 may include portable electronic devices such as a mobile phone, MP3 player and laptop computer or non-portable electronic devices such as a desktop computer, game machine, TV and projector.

The memory system 110 may operate to store data for the host 102 in response to a request of the host 102. Non-limited examples of the memory system 110 may include a solid state drive (SSD), a multi-media card (MMC), a secure digital (SD) card, a universal storage bus (USB) device, a universal flash storage (UFS) device, compact flash (CF) card, a smart media card (SMC), a personal computer memory card international association (PCMCIA) card and memory stick. The MMC may include an embedded MMC (eMMC), reduced size MMC (RS-MMC) and micro-MMC, and the SD card may include a mini-SD card and micro-SD card.

The memory system 110 may be embodied by various types of storage devices. Non-limited examples of storage devices included in the memory system 110 may include volatile memory devices such as a DRAM dynamic random access memory (DRAM) and a static RAM (SRAM) and nonvolatile memory devices such as a read only memory (ROM), a mask ROM (MROM), a programmable ROM (PROM), an erasable programmable ROM (EPROM), an electrically erasable programmable ROM (EEPROM), a ferroelectric RAM (FRAM), a phase-change RAM (PRAM), a magneto-resistive RAM (MRAM), resistive RAM (RRAM) and a flash memory. The flash memory may have a 3-dimensional (3D) stack structure.

The memory system 110 may include a memory device 150 and a controller 130. The memory device 150 may store data for the host 120, and the controller 130 may control data storage into the memory device 150.

The controller 130 and the memory device 150 may be integrated into a single semiconductor device, which may be included in the various types of memory systems as exemplified above.

Non-limited application examples of the memory system 110 may include a computer, an Ultra Mobile PC (UMPC), a workstation, a net-book, a Personal Digital Assistant (PDA), a portable computer, a web tablet, a tablet computer, a wireless phone, a mobile phone, a smart phone, an e-book, a Portable Multimedia Player (PMP), a portable game machine, a navigation system, a black box, a digital camera, a Digital Multimedia Broadcasting (DMB) player, a 3-dimensional television, a smart television, a digital audio recorder, a digital audio player, a digital picture recorder, a digital picture player, a digital video recorder, a digital video player, a storage device constituting a data center, a device capable of transmitting/receiving Information in a wireless environment, one of various electronic devices constituting a home network, one of various electronic devices constituting a computer network, one of various electronic devices constituting a telematics network, a Radio Frequency Identification (RFID) device, or one of various components constituting a computing system.

The memory device 150 may be a nonvolatile memory device and may retain data stored therein even though power is not supplied. The memory device 150 may store data provided from the host 102 through a write operation, and provide data stored therein to the host 102 through a read operation. The memory device 150 may include a plurality of memory dies (not shown), each memory die including a plurality of planes (not shown), each plane including a plurality of memory blocks 152 to 156, each of the memory blocks 152 to 156 may include a plurality of pages, and each of the pages may include a plurality of memory cells coupled to a word line.

The controller 130 may control the memory device 150 in response to a request from the host 102. For example, the controller 130 may provide data read from the memory device 150 to the host 102, and store data provided from the host 102 into the memory device 150. For this operation, the controller 130 may control read, write, program and erase operations of the memory device 150.

The controller 130 may include a host interface (I/F) unit 132, a processor 134, an error correction code (ECC) unit 138, a Power Management Unit (PMU) 140, a memory device controller such as a NAND flash controller (NFC) 142 and a memory 144 all operatively coupled via an internal bus.

The host interface unit 132 may be configured to process a command and data of the host 102, and may communicate with the host 102 through one or more of various interface protocols such as universal serial bus (USB), multi-media card (MMC), peripheral component interconnect-express (PCI-E), small computer system interface (SCSI), serial-attached SCSI (SAS), serial advanced technology attachment (SATA), parallel advanced technology attachment (PATA), enhanced small disk interface (ESDI), integrated drive electronics (IDE) and mobile industry processor interface (MIPI).

The ECC unit 138 may detect and correct an error contained in the data read from the memory device 150. In other words, the ECC unit 138 may perform an error correction decoding process to the data read from the memory device 150 through an ECC code used during an ECC encoding process. According to a result of the error correction decoding process, the ECC unit 138 may output a signal, for example, an error correction success/fail signal. When the number of error bits is more than a threshold value of correctable error bits, the ECC unit 138 may not correct the error bits, and may output an error correction fail signal.

The ECC unit 138 may perform error correction through a coded modulation such as Low Density Parity Check (LDPC) code, Bose-Chaudhri-Hocquenghem (BCH) code, turbo code, Reed-Solomon code, convolution code, Recursive Systematic Code (RSC), Trellis-Coded Modulation (TCM) and Block coded modulation (BCM). However, the ECC unit 138 is not limited thereto. The ECC unit 138 may include all circuits, modules, systems or devices for error correction.

The PMU 140 may provide and manage power of the controller 130.

The memory device controller 142 may serve as a memory/storage interface for interfacing the controller 130 and the memory device 150 such that the controller 130 controls the memory device 150 in response to a request from the host 102. When the memory device 150 is a flash memory or specifically a NAND flash memory, the memory device controller 142 may be an NFC and may generate a control signal for the memory device 150 and process data to be provided to the memory device 150 under the control of the processor 134. The memory device controller 142 may work as an interface (e.g., a NAND flash interface) for processing a command and data between the controller 130 and the memory device 150. Specifically, the memory device controller 142 may support data transfer between the controller 130 and the memory device 150.

The memory 144 may serve as a working memory of the memory system 110 and the controller 130, and store data for driving the memory system 110 and the controller 130. The controller 130 may control the memory device 150 to perform read, write, program and erase operations in response to a request from the host 102. The controller 130 may provide data read from the memory device 150 to the host 102, may store data provided from the host 102 into the memory device 150. The memory 144 may store data required for the controller 130 and the memory device 150 to perform these operations.

The memory 144 may be embodied by a volatile memory. For example, the memory 144 may be embodied by static random access memory (SRAM) or dynamic random access memory (DRAM). The memory 144 may be disposed within or out of the controller 130. FIG. 1 exemplifies the memory 144 disposed within the controller 130. In an embodiment, the memory 144 may be embodied by an external volatile memory having a memory interface transferring data between the memory 144 and the controller 130.

The processor 134 may control the operations of the memory system 110. The processor 134 may drive firmware to control the operations of the memory system 110. The firmware may be referred to as flash translation layer (FTL).

The processor 134 of the controller 130 may include a management unit (not illustrated) for performing a bad management operation of the memory device 150. The management unit may perform a bad block management operation of checking a bad block, in which a program fail occurs due to the characteristic of a NAND flash memory during a program operation, among the plurality of memory blocks 152 to 156 included in the memory device 150. The management unit may write the program-failed data of the bad block to a new memory block. In the memory device 150 having a 3D stack structure, the bad block management operation may reduce the use efficiency of the memory device 150 and the reliability of the memory system 110. Thus, the bad block management operation needs to be performed with more reliability.

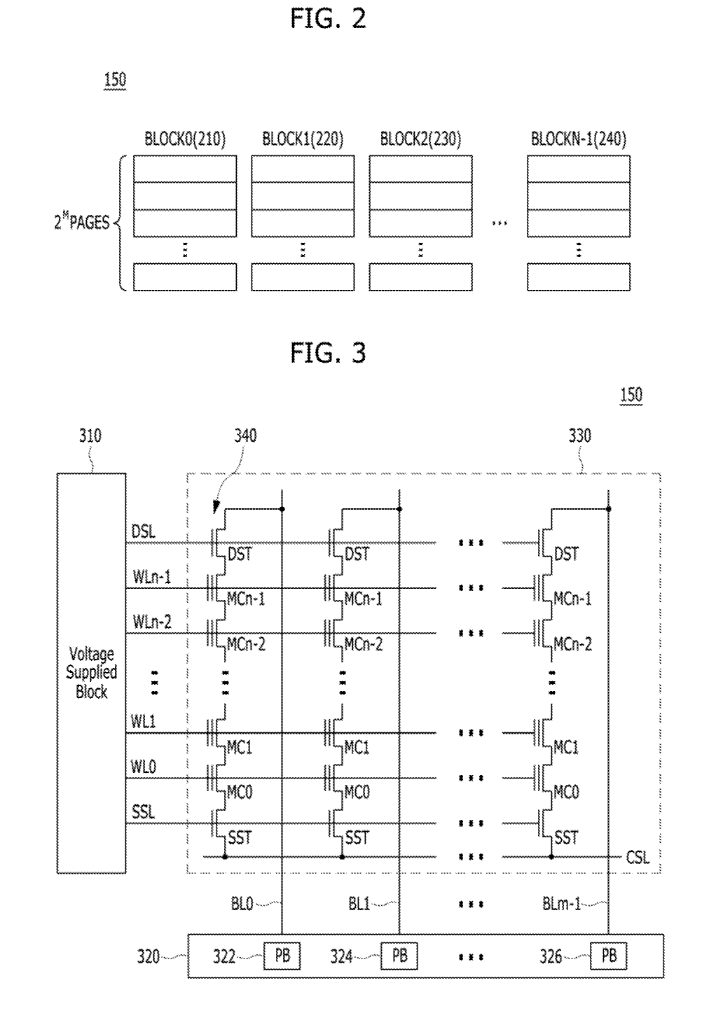

FIG. 2 is a schematic diagram illustrating the memory device 150.

Referring to FIG. 2, the memory device 150 may include a plurality of memory blocks 0 to N−1, and each of the blocks 0 to N−1 may include a plurality of pages, for example, 2^{M} pages, the number of which may vary according to circuit design. Memory cells included in the respective memory blocks 0 to N−1 may be one or more of a single level cell (SLC) storing 1-bit data, or a multi-level cell (MLC) storing 2- or more bit data. An MLC storing 3-bit data is also referred to as a triple level cell (TLC), and an MLC storing 4-bit data is also referred to as a quadruple level cell (QLC).

FIG. 3 is a circuit diagram illustrating an exemplary configuration of a memory cell array of a memory block in the memory device 150.

Referring to FIG. 3, a memory block 330 which may correspond to any of the plurality of memory blocks 152 to 156 included in the memory device 150 of the memory system 110 may Include a plurality of cell strings 340 coupled to a plurality of corresponding bit lines BL0 to BLm−1. The cell string 340 of each column may Include one or more drain select transistors DST and one or more source select transistors SST. Between the drain and source select transistors DST and SST, a plurality of memory cells MC0 to MCn−1 may be coupled in series. In an embodiment, each of the memory cell transistors MC0 to MCn−1 may be embodied by an MLC capable of storing data information of a plurality of bits. Each of the cell strings 340 may be electrically coupled to a corresponding bit line among the plurality of bit lines BL0 to BLm−1. For example, as illustrated in FIG. 3, the first cell string is coupled to the first bit line BL0, and the last cell string is coupled to the last bit line BLm−1.

Although FIG. 3 illustrates NAND flash memory cells, the Invention is not limited in this way. It is noted that the memory cells may be NOR flash memory cells, or hybrid flash memory cells including two or more kinds of memory cells combined therein. Also, it is noted that the memory device 150 may be a flash memory device including a conductive floating gate as a charge storage layer or a charge trap flash (CTF) memory device including an insulation layer as a charge storage layer.

The memory device 150 may further include a voltage supply unit 310 which provides word line voltages including a program voltage, a read voltage and a pass voltage to supply to the word lines according to an operation mode. The voltage generation operation of the voltage supply unit 310 may be controlled by a control circuit (not illustrated). Under the control of the control circuit, the voltage supply unit 310 may select one of the memory blocks (or sectors) of the memory cell array, select one of the word lines of the selected memory block, and provide the word line voltages to the selected word line and the unselected word lines.

The memory device 150 may include a read/write circuit 320 which is controlled by the control circuit. During a verification/normal read operation, the read/write circuit 320 may operate as a sense amplifier for reading data from the memory cell array. During a program operation, the read/write circuit 320 may operate as a write driver for driving bit lines according to data to be stored in the memory cell array. During a program operation, the read/write circuit 320 may receive from a buffer (not illustrated) data to be stored into the memory cell array, and drive bit lines according to the received data. The read/write circuit 320 may include a plurality of page buffers 322 to 326 respectively corresponding to columns (or bit lines) or column pairs (or bit line pairs), and each of the page buffers 322 to 326 may include a plurality of latches (not illustrated).

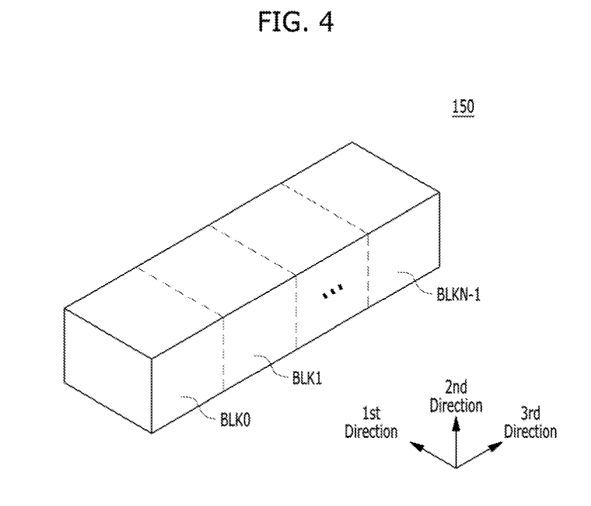

FIG. 4 is a schematic diagram illustrating an exemplary 3D structure of the memory device 150.

The memory device 150 may be embodied by a 2D or 3D memory device. Specifically, as illustrated in FIG. 4, the memory device 150 may be embodied by a nonvolatile memory device having a 3D stack structure. When the memory device 150 has a 3D structure, the memory device 150 may include a plurality of memory blocks BLK0 to BLKN−1 each of the memory blocks having a 3D structure (or vertical structure).

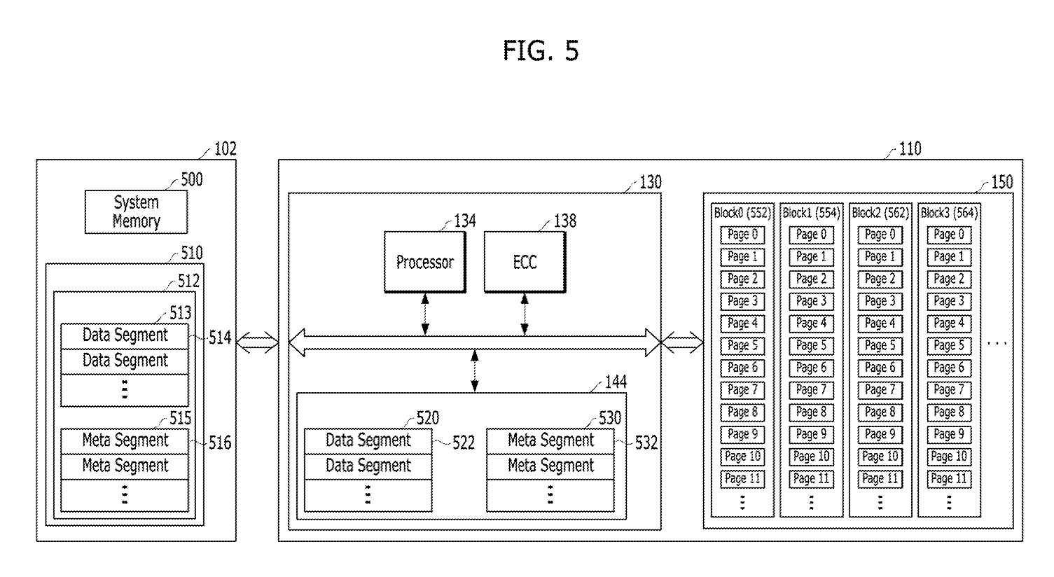

FIG. 5 is a diagram schematically illustrating further elements of the data processing system 100, in accordance with an embodiment of the present invention.

As described above, the data processing system 100 may include the host 102 and the memory system 110, and the memory system 110 may include the controller 130 and the memory device 150.

The host 102 may include a system memory 500 and a main memory 510. The system memory 500 may store system data (e.g., data about a file system or an operating system) of the host 102 and program information. The main memory 510 may store data corresponding to a command to the memory system 110. A part of the main memory 510 may be set as a unified memory (UM) region 512 according to a request of the memory system 110. The host 102 may write data into the UM region 512 and read data from the UM region 512 in response to a request from the memory system 110.

The processor 134 of the controller 130 may process a command received from the host 102. In processing the received command, the processor 134 may use the memory 144 of the controller 130. The processor 134 of the controller 130 may also process a command from the host 102 by using the UM region 512 of the host 102. In other words, when the processor 134 processes a command received from the host 102, the processor 134 may process the command from the host 102 by storing data corresponding to the received command into the memory 144 of the controller 130 or into the UM region 512 of the host 102. The received command may be, for example, a read command or a write command.

When the controller 130 receives a command from the host 102, the processor 134 may process the received command by selecting one of the memory 144 of the controller 130 and the UM region 512 of the host 102 according to a predetermined criterion of the controller 130.

The predetermined criterion may be whether the UM region 512 has storage capability of storing further data. For example, when there is an invalid data segment among data segments 514 stored in a first buffer 513 of the UM region 512, the processor 134 may determine that the UM region 512 has storage capability of storing further data and accordingly may process a command from the host 102 by using the UM region 512. In other words, the processor 134 may erase the invalid data segment stored in the first buffer 513 of the UM region 512 of the host 102, and then may process a command from the host 102 by using the UM region 512.

For example, when the processor 134 processes a write command received from the host 102 by using the UM region 512 of the host 102, the processor 134 may store user data corresponding to the write command into the first buffer 513 in the UM region 512 of the host 102, then may encode data segments 514 stored in the first buffer 513 through the ECC unit 138, and then may store the encoded data into pages of memory blocks 552, 554, 562 and 564 of the memory device 150. The processor 134 may generate or update metadata for the user data stored in the memory blocks 552, 554, 562 and 564 and then store the generated or updated metadata for the user data into a second buffer 515 in the UM region 512 of the host 102 after the processor 134 writes the encoded data segments 514 (i.e., the user data corresponding to the write command) into the pages of the memory blocks 552, 554, 562 and 564. In other words, the processor 134 may store meta segments 516 of the metadata into the second buffer 515 in the UM region 512 of the host 102. The processor 134 may write the data segments 514 into an open memory block or a free memory block, to which an erase operation is performed among the memory blocks 552, 554, 562 and 564.

The metadata may include first and second map data. The first map data may include logical-to-physical (L2P) information for data stored in the memory blocks. The second map data may include physical-to-logical (P2L) information for data stored in the memory blocks. The metadata may further include information for data corresponding to a command provided from the host 102, for a command operation corresponding to the command, for memory blocks of the memory device 150 to which the command operation is performed, and for map data corresponding to the command operation. In other words, the metadata may include substantially all information except for user data corresponding to the command provided from the host 102.

In order for the processor 134 to store into the first buffer 513 user data corresponding to a write command, the processor 134 may request the host 102 to write the user data into the UM region 512 and the host 102 may store the user data into the first buffer 513 in response to the request for the user data from the processor 134. In order for the processor 134 to store into the second buffer 515 the first and second map data, the processor 134 may request the host 102 to write the first and second map data into the UM region 512 and the host 102 may store the first and second map data into the second buffer 515 in response to the request for the first and second map data from the processor 134. In other words, in order for the processor 134 to store data into the UM region 512, the processor 134 may request the host 102 to write the data into the UM region 512 and the host 102 may store the data into the UM region 512 in response to the request for the data from the processor 134.

In order for the processor 134 to read user data from the first buffer 513, the processor 134 may request the host 102 to read the user data from the UM region 512 and the host 102 may read the user data from the first buffer 513 in response to the request for the user data from the processor 134. In order for the processor 134 to read the first and second map data from the second buffer 515, the processor 134 may request the host 102 to read the first and second map data from the UM region 512 and the host 102 may read the first and second map data from the second buffer 515 in response to the request for the first and second map data from the processor 134. In other words, in order for the processor 134 to read data from the UM region 512, the processor 134 may request the host 102 to read the data from the UM region 512 and the host 102 may read the data from the UM region 512 in response to the request for the data from the processor 134.

When the processor 134 processes a write command by using the UM region 512 of the host 102, the processor 134 may store user data corresponding to a first write command provided from the host 102 into the first buffer 513 in the UM region 512 of the host 102, may store user data corresponding to a second write command provided from the host 102 into a first buffer 520 in the memory 144 of the controller 130, may encode the data segments 514 stored in the first buffer 513 of the UM region 512 and data segments 522 stored in the first buffer 520 of the memory 144 through the ECC unit 138, and then may store the encoded data into pages of the memory blocks 552, 554, 562 and 564 in the memory device 150.

When the processor 134 processes a write command by using the UM region 512 of the host 102, the processor 134 may store user data corresponding to a first write command provided from the host 102 into the first buffer 513 in the UM region 512 of the host 102, may add dummy data (e.g., NULL data) into the data segments 514 stored in the first buffer 513 when a size of the data segments 514 is smaller than a predetermined size (e.g., a size suitable for the one-shot program), may encode the dummy-added data segments 514 stored in the first buffer 513 of the UM region 512 through the ECC unit 138, and then may store the encoded data into pages of the memory blocks 552, 554, 562 and 564 in the memory device 150.

When the UM region 512 of the host 102 is not capable of storing further data, for example, when there is no invalid segment among the data segments 514 stored in the first buffer 513 of the UM region 512 in the host 102, the processor 134 may request the host 102 to increase the storage capacity of the UM region 512. When the host 102 increases the storage capacity of the UM region 512 in response to the request for the storage capacity of the UM region 512 provided from the processor 134, the processor 134 may process a command from the host 102 by using the increased storage capacity of the UM region 512. In other words, the processor 134 may process a command from the host 102 by increasing the storage capacity of the UM region 512 of the host 102.

For example, when the processor 134 processes a write command by using the memory 144 of the controller 130, the processor 134 may store user data corresponding to a write command provided from the host 102 into the first buffer 520 in the memory 144 of the controller 130, may encode the data segments 522 stored in the first buffer 520 of the memory 144 through the ECC unit 138, and then may store the encoded data into pages of the memory blocks 552, 554, 562 and 564 in the memory device 150. As the data segments 522 of the user data corresponding to the write command are written into the pages of the memory blocks 552, 554, 562 and 564, the processor 134 may generate or update metadata for the user data and may store the generated or updated metadata into the second buffer 530 in the memory 144 of the controller 130. In other words, the processor 134 may store meta segments 532 of the metadata into the second buffer 530 of the memory 144.

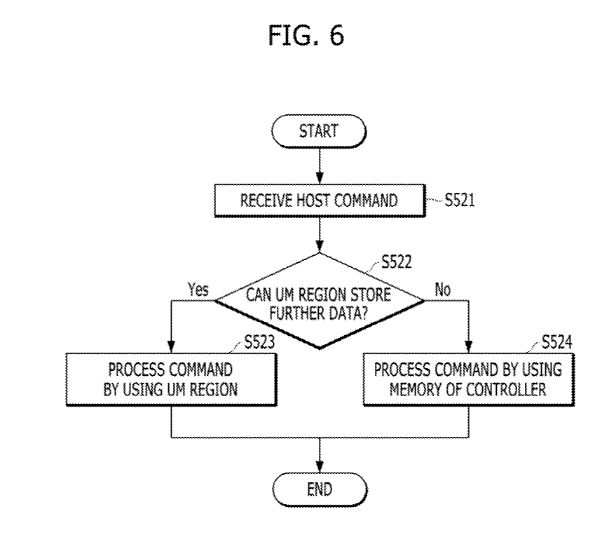

FIG. 6 is a flowchart illustrating an operation of the memory system 110, in accordance with an embodiment of the present invention.

When the controller 130 receives a command from the host 102 at step S521, the processor 134 of the controller 130 may determine whether the UM region 512 has a storage capacity for storing further data at step S522.

For example, the processor 134 may determine whether to process the provided command by using the UM region 512 according to a predetermined criterion. For example, when there is an invalid data segment among data segments 514 stored in the first buffer 513 of the UM region 512, the processor 134 may determine to process the provided command by using the UM region 512.

When the processor 134 determines to process the provided command by using the UM region 512 as a result of step S522, the processor 134 may process the provided command by using the UM region 512 at step S523.

Specifically, when the processor 134 processes a command, for example, a write command provided from the host 102 by using the UM region 512 of the host 102, the processor 134 may store user data corresponding to the write command into the first buffer 513 in the UM region 512 of the host 102, then may encode data segments 514 stored in the first buffer 513 through the ECC unit 138, and then may store the encoded data into pages of memory blocks 552, 554, 562 and 564 of the memory device 150. As the data segments 514 stored in the first buffer 513 are written into the pages of the memory blocks 552, 554, 562 and 564, the data segments 514 stored in the first buffer 513 become invalid and the data segments 514 stored in the pages of the memory blocks 552, 554, 562 and 564 become valid. As the data segments 514 of the user data corresponding to the write command are written into the pages of the memory blocks 552, 554, 562 and 564, the processor 134 may generate or update metadata for the user data stored in the memory blocks 552, 554, 562 and 564 and then store the generated or updated metadata for the user data into the second buffer 515 in the UM region 512 of the host 102.

When the processor 134 determines not to process the provided command by using the UM region 512 as a result of step S522 since the UM region 512 is determined not to have sufficient storage capability for storing further data, the processor 134 may process the provided command by using the memory 144 of the controller 130 at step S524.

Specifically, the processor 134 may store user data corresponding to a command, for example, a write command provided from the host 102 into the first buffer 520 in the memory 144 of the controller 130, may encode the data segments 522 stored in the first buffer 520 of the memory 144 through the ECC unit 138, and then may store the encoded data into pages of the memory blocks 552, 554, 562 and 564 in the memory device 150. As the data segments 522 of the user data corresponding to the write command are written into the pages of the memory blocks 552, 554, 562 and 564, the data segments 522 stored in the first buffer 520 may become invalid and the data segments 522 stored in the pages of the memory blocks 552, 554, 562 and 564 may become valid. As the data segments 522 of the user data corresponding to the write command are written into the pages of the memory blocks 552, 554, 562 and 564, the processor 134 may generate or update metadata for the user data and may store the generated or updated metadata into the second buffer 530 in the memory 144 of the controller 130.

As described above, in accordance with an embodiment of the present invention, the memory system 110 may reduce the time that is required for storing into a memory location data corresponding to a command received from the host 102 by processing the data corresponding to the command through the UM region 512 of the host 102. Accordingly, in accordance with an embodiment of the present invention, the memory system 110 may process the command received from the host 102 more promptly, i.e., in a shorter period of time than existing memory systems.

Further, as described above, in accordance with an embodiment of the present invention, the memory system 110 may process the command from the host 102 by selecting one of the memory 144 of the controller 130 and the UM region 512 of the host 102 according to a predetermined criterion for storing the data corresponding to the command received from the host 102. Accordingly, in accordance with an embodiment of the present invention, the memory system 110 may more promptly process the command from the host 102.

Further, as described above, in accordance with an embodiment of the present invention, the memory system 110 may use the main memory of the host 102 for the memory system 110 itself. Accordingly, the performance of the memory system 110 may be improved.

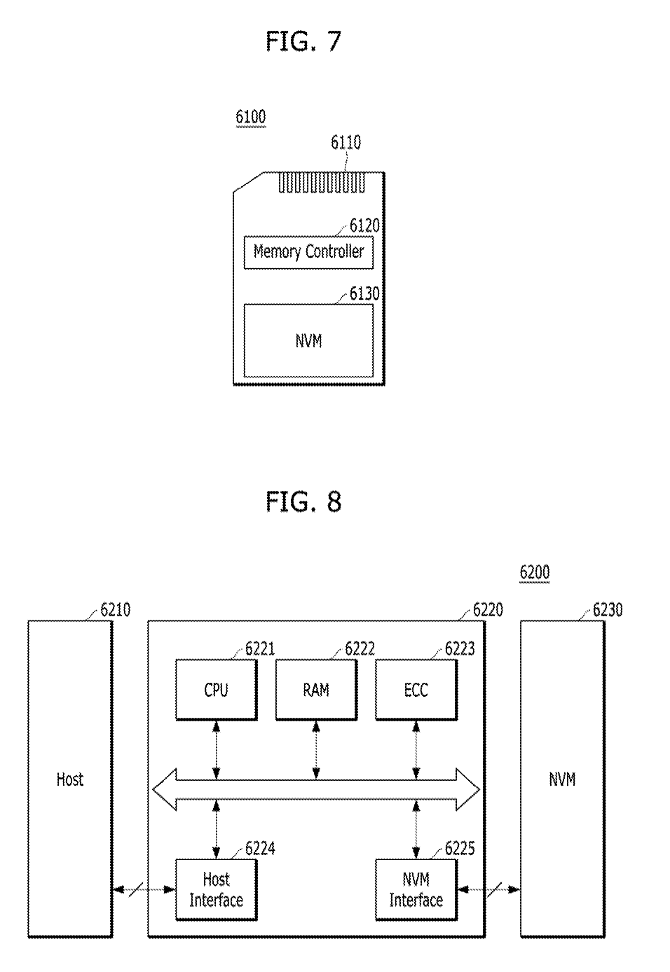

FIGS. 7 to 15 are diagrams schematically illustrating application examples of the data processing system of FIGS. 1 to 6 according to various embodiments.

FIG. 7 is a diagram schematically illustrating another example of the data processing system including the memory system in accordance with the present embodiment. FIG. 7 schematically Illustrates a memory card system to which the memory system in accordance with the present embodiment is applied.

Referring to FIG. 7, the memory card system 6100 may include a memory controller 6120, a memory device 6130 and a connector 6110.

More specifically, the memory controller 6120 may be connected to the memory device 6130 embodied by a nonvolatile memory, and configured to access the memory device 6130. For example, the memory controller 6120 may be configured to control read, write, erase and background operations of the memory device 6130. The memory controller 6120 may be configured to provide an interface between the memory device 6130 and a host, and drive firmware for controlling the memory device 6130. That is, the memory controller 6120 may correspond to the controller 130 of the memory system 110 described with reference to FIGS. 1 to 6, and the memory device 6130 may correspond to the memory device 150 of the memory system 110 described with reference to FIGS. 1 to 6.

Thus, the memory controller 6120 may include a RAM, a processing unit, a host interface, a memory interface and an error correction unit. The memory controller 130 may further Include the elements described in FIGS. 1 and 6.

The memory controller 6120 may communicate with an external device, for example, the host 102 of FIG. 1 through the connector 6110. For example, as described with reference to FIG. 1, the memory controller 6120 may be configured to communicate with an external device through one or more of various communication protocols such as universal serial bus (USB), multimedia card (MMC), embedded MMC (eMMC), peripheral component interconnection (PCI), PCI express (PCIe), Advanced Technology Attachment (ATA), Serial-ATA, Parallel-ATA, small computer system interface (SCSI), enhanced small disk interface (EDSI), Integrated Drive Electronics (IDE), Firewire, universal flash storage (UFS), WIFI and Bluetooth. Thus, the memory system and the data processing system in accordance with the present embodiment may be applied to wired/wireless electronic devices or particularly mobile electronic devices.

The memory device 6130 may be implemented by a nonvolatile memory. For example, the memory device 6130 may be implemented by various nonvolatile memory devices such as an erasable and programmable ROM (EPROM), an electrically erasable and programmable ROM (EEPROM), a NAND flash memory, a NOR flash memory, a phase-change RAM (PRAM), a resistive RAM (ReRAM), a ferroelectric RAM (FRAM) and a spin torque transfer magnetic RAM (STT-RAM). The memory device 6130 may include a plurality of dies as in the memory device 150 of FIG. 5.

The memory controller 6120 and the memory device 6130 may be integrated into a single semiconductor device. For example, the memory controller 6120 and the memory device 6130 may construct a solid state driver (SSD) by being integrated into a single semiconductor device. Also, the memory controller 6120 and the memory device 6130 may construct a memory card such as a PC card (PCMCIA: Personal Computer Memory Card International Association), a compact flash (CF) card, a smart media card (e.g., SM and SMC), a memory stick, a multimedia card (e.g., MMC, RS-MMC, MMCmicro and eMMC), an SD card (e.g., SD, miniSD, microSD and SDHC) and a universal flash storage (UFS).

FIG. 8 is a diagram schematically illustrating another example of the data processing system including a memory system, in accordance with the present embodiment.

Referring to FIG. 8, the data processing system 6200 may include a memory device 6230 having one or more nonvolatile memories and a memory controller 6220 for controlling the memory device 6230. The data processing system 6200 illustrated in FIG. 8 may serve as a storage medium such as a memory card (CF, SD, micro-SD or the like) or USB device, as described with reference to FIG. 1. The memory device 6230 may correspond to the memory device 150 in the memory system 110 described in FIGS. 1 to 6, and the memory controller 6220 may correspond to the controller 130 in the memory system 110 described in FIGS. 1 to 6.

The memory controller 6220 may control a read, write or erase operation on the memory device 6230 in response to a request of the host 6210, and the memory controller 6220 may include one or more CPUs 6221, a buffer memory such as RAM 6222, an ECC circuit 6223, a host interface 6224 and a memory interface such as an NVM interface 6225.

The CPU 6221 may control the operations on the memory device 6230, for example, read, write, file system management and bad page management operations. The RAM 6222 may be operated according to control of the CPU 6221, and used as a work memory, buffer memory or cache memory. When the RAM 6222 is used as a work memory, data processed by the CPU 6221 may be temporarily stored in the RAM 6222. When the RAM 6222 is used as a buffer memory, the RAM 6222 may be used for buffering data transmitted to the memory device 6230 from the host 6210 or transmitted to the host 6210 from the memory device 6230. When the RAM 6222 is used as a cache memory, the RAM 6222 may assist the low-speed memory device 6230 to operate at high speed.

The ECC circuit 6223 may correspond to the ECC unit 138 of the controller 130 illustrated in FIG. 1. As described with reference to FIG. 1, the ECC circuit 6223 may generate an ECC (Error Correction Code) for correcting a fail bit or error bit of data provided from the memory device 6230. The ECC circuit 6223 may perform error correction encoding on data provided to the memory device 6230, thereby forming data with a parity bit. The parity bit may be stored in the memory device 6230. The ECC circuit 6223 may perform error correction decoding on data outputted from the memory device 6230. At this time, the ECC circuit 6223 may correct an error using the parity bit. For example, as described with reference to FIG. 1, the ECC circuit 6223 may correct an error using the LDPC code, BCH code, turbo code, Reed-Solomon code, convolution code, RSC or coded modulation such as TCM or BCM.

The memory controller 6220 may transmit/receive data to/from the host 6210 through the host interface 6224, and transmit/receive data to/from the memory device 6230 through the NVM interface 6225. The host interface 6224 may be connected to the host 6210 through a PATA bus, SATA bus, SCSI, USB, PCIe or NAND interface. The memory controller 6220 may have a wireless communication function with a mobile communication protocol such as WiFi or Long Term Evolution (LTE). The memory controller 6220 may be connected to an external device, for example, the host 6210 or another external device, and then transmit/receive data to/from the external device. In particular, as the memory controller 6220 is configured to communicate with the external device through one or more of various communication protocols, the memory system and the data processing system in accordance with the present embodiment may be applied to wired/wireless electronic devices or particularly a mobile electronic device.

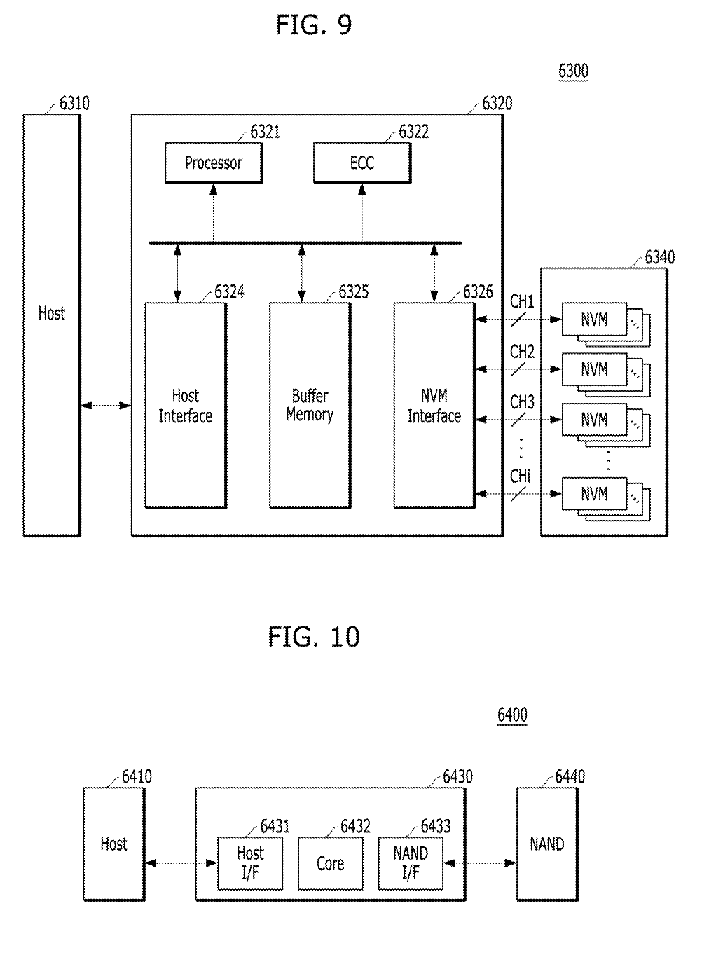

FIG. 9 is a diagram schematically illustrating another example of the data processing system including the memory system in accordance with the present embodiment. FIG. 9 schematically illustrates an SSD to which the memory system in accordance with the present embodiment is applied.

Referring to FIG. 9, the SSD 6300 may include a controller 6320 and a memory device 6340 including a plurality of nonvolatile memories. The controller 6320 may correspond to the controller 130 in the memory system 110 of FIGS. 1 and 6, and the memory device 6340 may correspond to the memory device 150 in the memory system of FIGS. 1 and 6.

More specifically, the controller 6320 may be connected to the memory device 6340 through a plurality of channels CH1 to CHi. The controller 6320 may include one or more processors 6321, a buffer memory 6325, an ECC circuit 6322, a host interface 6324 and a memory interface, for example, a nonvolatile memory interface 6326.

The buffer memory 6325 may temporarily store data provided from the host 6310 or data provided from a plurality of flash memories NVM included in the memory device 6340, or temporarily store meta data of the plurality of flash memories NVM, for example, map data including a mapping table. The buffer memory 6325 may be embodied by volatile memories such as DRAM, SDRAM, DDR SDRAM, LPDDR SDRAM and GRAM or nonvolatile memories such as FRAM, ReRAM, STT-MRAM and PRAM. For convenience of description, FIG. 9 illustrates that the buffer memory 6325 exists in the controller 6320. However, the buffer memory 6325 may exist outside the controller 6320.

The ECC circuit 6322 may calculate an ECC value of data to be programmed to the memory device 6340 during a program operation, perform an error correction operation on data read from the memory device 6340 based on the ECC value during a read operation, and perform an error correction operation on data recovered from the memory device 6340 during a failed data recovery operation.

The host interface 6324 may provide an interface function with an external device, for example, the host 6310, and the nonvolatile memory interface 6326 may provide an interface function with the memory device 6340 connected through the plurality of channels.

Furthermore, a plurality of SSDs 6300 to which the memory system 110 of FIGS. 1 and 6 is applied may be provided to embody a data processing system, for example, RAID (Redundant Array of Independent Disks) system. At this time, the RAID system may include the plurality of SSDs 6300 and a RAID controller for controlling the plurality of SSDs 6300. When the RAID controller performs a program operation in response to a write command provided from the host 6310, the RAID controller may select one or more memory systems or SSDs 6300 according to a plurality of RAID levels, that is, RAID level information of the write command provided from the host 6310 in the SSDs 6300, and output data corresponding to the write command to the selected SSDs 6300. Furthermore, when the RAID controller performs a read command in response to a read command provided from the host 6310, the RAID controller may select one or more memory systems or SSDs 6300 according to a plurality of RAID levels, that is, RAID level information of the read command provided from the host 6310 in the SSDs 6300, and provide data read from the selected SSDs 6300 to the host 6310.

FIG. 10 is a diagram schematically illustrating another example of the data processing system including the memory system in accordance with an embodiment. FIG. 10 schematically Illustrates an embedded Multi-Media Card (eMMC) to which the memory system in accordance with an embodiment is applied.

Referring to FIG. 10, the eMMC 6400 may include a controller 6430 and a memory device 6440 embodied by one or more NAND flash memories. The controller 6430 may correspond to the controller 130 in the memory system 110 of FIGS. 1 and 6, and the memory device 6440 may correspond to the memory device 150 in the memory system 110 of FIGS. 1 and 6.

More specifically, the controller 6430 may be connected to the memory device 6440 through a plurality of channels. The controller 6430 may include one or more cores 6432, a host interface 6431 and a memory interface, for example, a NAND Interface 6433.

The core 6432 may control the operations of the eMMC 6400, the host interface 6431 may provide an interface function between the controller 6430 and the host 6410, and the NAND interface 6433 may provide an interface function between the memory device 6440 and the controller 6430. For example, the host interface 6431 may serve as a parallel interface, for example, MMC interface as described with reference to FIG. 1. Furthermore, the host interface 6431 may serve as a serial interface, for example, UHS ((Ultra High Speed)-I/UHS-II) interface.

FIGS. 11 to 14 are diagrams schematically illustrating other examples of the data processing system including the memory system in accordance with an embodiment. FIGS. 11 to 14 schematically illustrate UFS (Universal Flash Storage) systems to which the memory system in accordance with an embodiment is applied.

Referring to FIGS. 11 to 14, the UFS systems 6500, 6600, 6700 and 6800 may include hosts 6510, 6610, 6710 and 6810, UFS devices 6520, 6620, 6720 and 6820 and UFS cards 6530, 6630, 6730 and 6830, respectively. The hosts 6510, 6610, 6710 and 6810 may serve as application processors of wired/wireless electronic devices or particularly mobile electronic devices, the UFS devices 6520, 6620, 6720 and 6820 may serve as embedded UFS devices, and the UFS cards 6530, 6630, 6730 and 6830 may serve as external embedded UFS devices or removable UFS cards.

The hosts 6510, 6610, 6710 and 6810, the UFS devices 6520, 6620, 6720 and 6820 and the UFS cards 6530, 6630, 6730 and 6830 in the respective UFS systems 6500, 6600, 6700 and 6800 may communicate with external devices, for example, wired/wireless electronic devices or particularly mobile electronic devices through UFS protocols, and the UFS devices 6520, 6620, 6720 and 6820 and the UFS cards 6530, 6630, 6730 and 6830 may be embodied by the memory system 110 illustrated in FIGS. 1 and 6. For example, in the UFS systems 6500, 6600, 6700 and 6800, the UFS devices 6520, 6620, 6720 and 6820 may be embodied in the form of the data processing system 6200, the SSD 6300 or the eMMC 6400 described with reference to FIGS. 8 to 10, and the UFS cards 6530, 6630, 6730 and 6830 may be embodied in the form of the memory card system 6100 described with reference to FIG. 7.

Furthermore, in the UFS systems 6500, 6600, 6700 and 6800, the hosts 6510, 6610, 6710 and 6810, the UFS devices 6520, 6620, 6720 and 6820 and the UFS cards 6530, 6630, 6730 and 6830 may communicate with each other through an UFS interface, for example, MIPI M-PHY and MIPI UniPro (Unified Protocol) in MIPI (Mobile Industry Processor Interface). Furthermore, the UFS devices 6520, 6620, 6720 and 6820 and the UFS cards 6530, 6630, 6730 and 6830 may communicate with each other through various protocols other than the UFS protocol, for example, UFDs, MMC, SD, mini-SD, and micro-SD.

In the UFS system 6500 illustrated in FIG. 11, each of the host 6510, the UFS device 6520 and the UFS card 6530 may include UniPro. The host 6510 may perform a switching operation in order to communicate with the UFS device 6520 and the UFS card 6530. In particular, the host 6510 may communicate with the UFS device 6520 or the UFS card 6530 through link layer switching, for example, L3 switching at the UniPro. At this time, the UFS device 6520 and the UFS card 6530 may communicate with each other through link layer switching at the UniPro of the host 6510. In the present embodiment, the configuration in which one UFS device 6520 and one UFS card 6530 are connected to the host 6510 has been exemplified for convenience of description. However, a plurality of UFS devices and UFS cards may be connected in parallel or in the form of a star to the host 6410, and a plurality of UFS cards may be connected in parallel or in the form of a star to the UFS device 6520 or connected in series or in the form of a chain to the UFS device 6520.

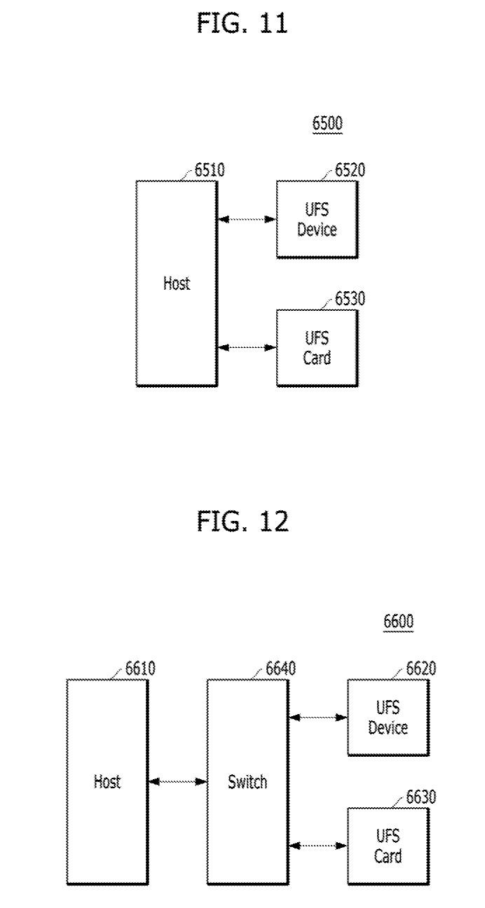

In the UFS system 6600 illustrated in FIG. 12, each of the host 6610, the UFS device 6620 and the UFS card 6630 may include UniPro, and the host 6610 may communicate with the UFS device 6620 or the UFS card 6630 through a switching module 6640 performing a switching operation, for example, through the switching module 6640 which performs link layer switching at the UniPro, for example, L3 switching. The UFS device 6620 and the UFS card 6630 may communicate with each other through link layer switching of the switching module 6640 at UniPro. In the present embodiment, the configuration in which one UFS device 6620 and one UFS card 6630 are connected to the switching module 6640 has been exemplified for convenience of description. However, a plurality of UFS devices and UFS cards may be connected in parallel or in the form of a star to the switching module 6640, and a plurality of UFS cards may be connected in series or in the form of a chain to the UFS device 6620.

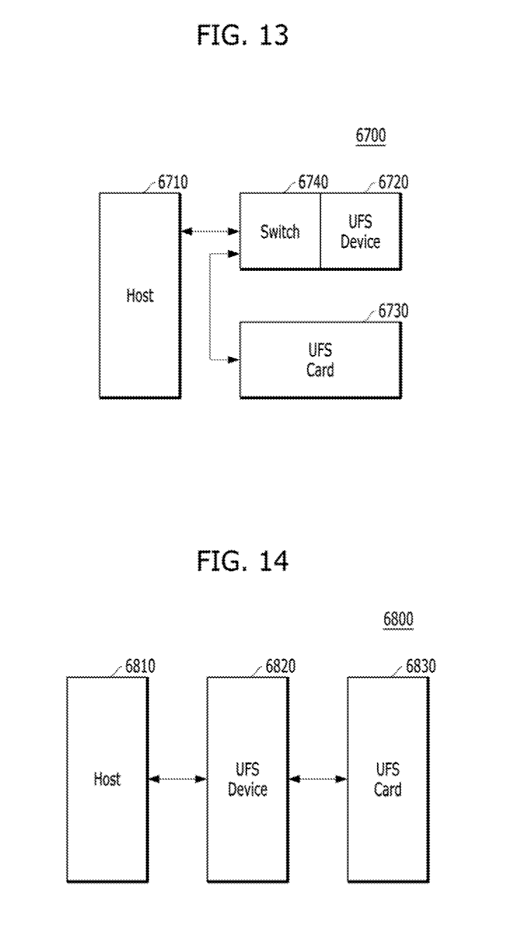

In the UFS system 6700 illustrated in FIG. 13, each of the host 6710, the UFS device 6720 and the UFS card 6730 may include UniPro, and the host 6710 may communicate with the UFS device 6720 or the UFS card 6730 through a switching module 6740 performing a switching operation, for example, through the switching module 6740 which performs link layer switching at the UniPro, for example, L3 switching. At this time, the UFS device 6720 and the UFS card 6730 may communicate with each other through link layer switching of the switching module 6740 at the UniPro, and the switching module 6740 may be integrated as one module with the UFS device 6720 inside or outside the UFS device 6720. In the present embodiment, the configuration in which one UFS device 6720 and one UFS card 6730 are connected to the switching module 6740 has been exemplified for convenience of description. However, a plurality of modules each including the switching module 6740 and the UFS device 6720 may be connected in parallel or in the form of a star to the host 6710 or connected in series or in the form of a chain to each other. Furthermore, a plurality of UFS cards may be connected in parallel or in the form of a star to the UFS device 6720.

In the UFS system 6800 illustrated in FIG. 14, each of the host 6810, the UFS device 6820 and the UFS card 6830 may include M-PHY and UniPro. The UFS device 6820 may perform a switching operation in order to communicate with the host 6810 and the UFS card 6830. In particular, the UFS device 6820 may communicate with the host 6810 or the UFS card 6830 through a switching operation between the M-PHY and UniPro module for communication with the host 6810 and the M-PHY and UniPro module for communication with the UFS card 6830, for example, through a target ID (Identifier) switching operation. At this time, the host 6810 and the UFS card 6830 may communicate with each other through target ID switching between the M-PHY and UniPro modules of the UFS device 6820. In the present embodiment, the configuration in which one UFS device 6820 is connected to the host 6810 and one UFS card 6830 is connected to the UFS device 6820 has been exemplified for convenience of description. However, a plurality of UFS devices may be connected in parallel or in the form of a star to the host 6810, or connected in series or in the form of a chain to the host 6810, and a plurality of UFS cards may be connected in parallel or in the form of a star to the UFS device 6820, or connected in series or in the form of a chain to the UFS device 6820.

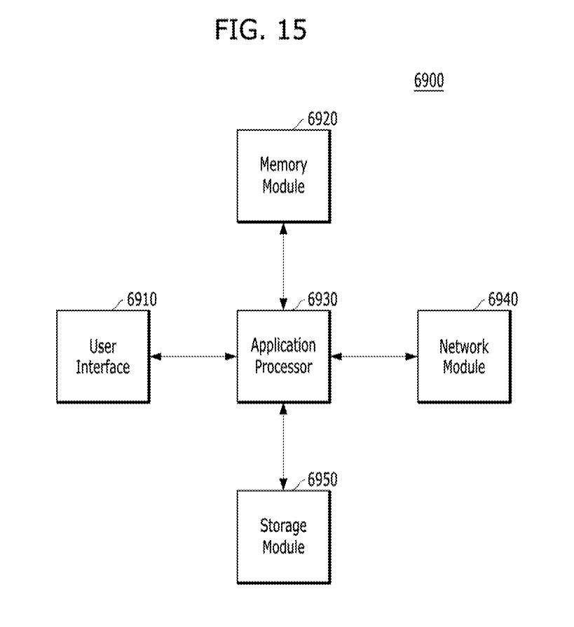

FIG. 15 is a diagram schematically illustrating another example of the data processing system including the memory system in accordance with an embodiment. FIG. 15 is a diagram schematically illustrating a user system to which the memory system in accordance with an embodiment is applied.

Referring to FIG. 15, the user system 6900 may include an application processor 6930, a memory module 6920, a network module 6940, a storage module 6950 and a user interface 6910.

More specifically, the application processor 6930 may drive components included in the user system 6900, for example, an OS, and include controllers, interfaces and a graphic engine which control the components included in the user system 6900. The application processor 6930 may be provided as a System-on-Chip (SoC).

The memory module 6920 may be used as a main memory, work memory, buffer memory or cache memory of the user system 6900. The memory module 6920 may include a volatile RAM such as DRAM, SDRAM, DDR SDRAM, DDR2 SDRAM, DDR3 SDRAM, LPDDR SDARM, LPDDR3 SDRAM or LPDDR3 SDRAM or a nonvolatile RAM such as PRAM, ReRAM, MRAM or FRAM. For example, the application processor 6930 and the memory module 6920 may be packaged and mounted, based on POP (Package on Package).

The network module 6940 may communicate with external devices. For example, the network module 6940 may not only support wired communication, but may also support various wireless communication protocols such as code division multiple access (CDMA), global system for mobile communication (GSM), wideband CDMA (WCDMA), CDMA-2000, time division multiple access (TDMA), long term evolution (LTE), worldwide interoperability for microwave access (Wimax), wireless local area network (WLAN), ultra-wideband (UWB), Bluetooth, wireless display (WI-DI), thereby communicating with wired/wireless electronic devices or particularly mobile electronic devices. Therefore, the memory system and the data processing system, in accordance with an embodiment of the present invention, can be applied to wired/wireless electronic devices. The network module 6940 may be included in the application processor 6930.

The storage module 6950 may store data, for example, data received from the application processor 6930, and then may transmit the stored data to the application processor 6930. The storage module 6950 may be embodied by a nonvolatile semiconductor memory device such as a phase-change RAM (PRAM), a magnetic RAM (MRAM), a resistive RAM (ReRAM), a NAND flash, NOR flash and 3D NAND flash, and provided as a removable storage medium such as a memory card or external drive of the user system 6900. The storage module 6950 may correspond to the memory system 110 described with reference to FIGS. 1 and 6. Furthermore, the storage module 6950 may be embodied as an SSD, eMMC and UFS as described above with reference to FIGS. 9 to 14.

The user interface 6910 may include interfaces for inputting data or commands to the application processor 6930 or outputting data to an external device. For example, the user interface 6910 may include user input interfaces such as a keyboard, a keypad, a button, a touch panel, a touch screen, a touch pad, a touch ball, a camera, a microphone, a gyroscope sensor, a vibration sensor and a piezoelectric element, and user output interfaces such as a liquid crystal display (LCD), an organic light emitting diode (OLED) display device, an active matrix OLED (AMOLED) display device, an LED, a speaker and a motor.

Furthermore, when the memory system 110 of FIGS. 1 and 6 is applied to a mobile electronic device of the user system 6900, the application processor 6930 may control the operations of the mobile electronic device, and the network module 6940 may serve as a communication module for controlling wired/wireless communication with an external device. The user interface 6910 may display data processed by the processor 6930 on a display/touch module of the mobile electronic device, or support a function of receiving data from the touch panel.

While the present invention has been described with respect to specific embodiments, it will be apparent to those skilled in the art that various changes and modifications may be made without departing from the spirit and scope of the invention as defined in the following claims.

What is claimed is:

1. A controller comprising:
a processor suitable for:
determining whether to store further data corresponding to a command received from a host into a first region in a main memory of the host when receiving the command from the host,
requesting the host to store the further data corresponding to the command into the first region of the main memory when the first region is determined to store the further data corresponding to the command; and
an error correction code unit suitable for encoding the further data stored in the first region in response to the storage request,
wherein the processor controls a memory device to store the encoded data.

2. The controller of claim 1, wherein the first region is a part of the main memory of the host, into which the host stores the further data corresponding to the command in response to the storage request.

3. The controller of claim 2, wherein the processor determines to store the further data into the first region in the main memory of the host when there is an invalid data among data stored in the first region.

4. The controller of claim 3, wherein when the further data corresponding to the command is stored into the first region of the main memory and then stored in the memory device, the further data stored in the first region of the main memory becomes invalid.

5. The controller of claim 2, wherein the processor further requests the host to increase a storage capacity of the first region of the main memory when the processor determines not to store the further data into the first region in the main memory.

6. The controller of claim 5, wherein when the host increases the storage capacity of the first region of the main memory, the processor requests the host to store data corresponding to the command through the increased storage capacity of the first region.

7. The controller of claim 2,
wherein the processor further generates metadata for the encoded data stored in the memory device, and
wherein the processor further requests the host to store the metadata into a second region of the main memory.

8. The controller of claim 7, wherein the second region is a part of the main memory, into which the host stores the metadata in response to the storage request.

9. The controller of claim 2, wherein when a size of the data corresponding to the command stored in the first region is smaller than a predetermined size, the error correction code unit adds dummy data to the data corresponding to the command stored in the first region before encoding the data stored in the first region.

10. The controller of claim 2,
further comprising a memory,
wherein the processor further stores the data corresponding to the command into the memory when processor determines not to store data into the first region in the main memory, and
wherein the error correction code unit further encodes the data corresponding to the command stored in the memory.

11. An operating method of a controller including a processor and an error correction code unit, the method comprising:
determining, by the processor, whether to store further data corresponding to a command received from a host into a first region of a main memory of the host when the processor receives the command from the host;
requesting, by the processor, the host to store the further data corresponding to the received command into the first region of the main memory when the first region of the main memory is determined to store the further data corresponding to the received command;
encoding, by the error correction code, data stored in the first region in response to the storage request; and
controlling, by the processor, a memory device to store the encoded data.

12. The method of claim 11, wherein the first region is a part of the main memory, into which the host stores the further data corresponding to the command in response to the storage request.

13. The method of claim 12, wherein the determining is performed by determining to store the further data corresponding to the received command into the first region in the main memory of the host when there is an invalid data among data stored in the first region.

14. The method of claim 13, wherein when the further data corresponding to the command is stored into the first region of the main memory and then stored in the memory device, the further data stored in the first region of the main memory becomes invalid.

15. The method of claim 12, further comprising requesting, by the processor, the host to increase a storage capacity of the first region of the main memory when the processor determines not to store the further data corresponding to the received command into the first region in the main memory.

16. The method of claim 15, wherein when the storage capacity of the first region of the main memory is increased by the host, the requesting by the processor is performed to store data corresponding to the command through the increased storage capacity of the first region.

17. The method of claim 12, further comprising:
generating, by the processor, metadata for the encoded data stored in the memory device; and
requesting, by the processor, the host to store the metadata into a second region of the main memory.

18. The method of claim 17, wherein the second region is a part of the main memory, into which the host stores the metadata in response to the storage request.

19. The method of claim 12, wherein when a size of the further data corresponding to the command stored in the first region is smaller than a predetermined size, the encoding by the error correction code unit includes adding dummy data to the data corresponding to the command stored in the first region before encoding the further data stored in the first region.

20. The method of claim 12, further comprising:
storing, by the processor, the data corresponding to the command into the memory when processor determines not to store the further data into the first region in the main memory, and
encoding, by the error correction code unit, the further data corresponding to the command stored in the main memory.
